(19) United States
(12) Patent Application Publication
(10) Pub. No.: US 2020/0095442 A1
(43) Pub. Date: Mar. 26, 2020

(54) FLOCCULATES OF METALLIC, GEOMETRICALLY DISCRETE NANOPARTICLES COMPOSITIONS AND METHODS OF FORMING THE SAME

(71) Applicant: NANO DIMENSIONS TECHNOLOGIES LTD., Nes Ziona (IL)

(72) Inventor: Lior Yedidya, Nes Ziona (IL)

(21) Appl. No.: 16/619,577

(22) PCT Filed: Jun. 5, 2017
(86) PCT No.: PCT/US2017/035885

§ 371 Date: Dec. 5, 2019

(51) Int. Cl. C09D 11/322; C09D 11/52; H05K 1/09

(52) U.S. Cl. CPC C09D 11/322; C09D 11/52; B82Y 30/00; H05K 2203/1157; H05K 1/097

(57) ABSTRACT

The disclosure relates to flocs of metallic, geometrically discrete copper nanoparticles. Specifically, the disclosure relates to a process for obtaining flocs, or clusters of oxidation-resistant, stable Copper nano-particles, the flocs being capable of being sintered in ambient environment at relatively low temperatures.

### BACKGROUND

The disclosure is directed to methods and compositions for obtaining discrete flocculates of metallic, geometrically discrete nanoparticles. Specifically, the disclosure is directed to a process for obtaining flocculates of oxidation-resistant, stable Copper nanoparticles capable of being sintered in ambient environment at relatively low heat.

A large portion of the conductive components in electronic devices produced to-date are made of copper. This is due to the high conductivity of copper and its relatively low price. Nowadays, there is a growing market of printed electronics in which electronic devices are manufactured by printing technology. For instance, screen and ink-jet printing.

In order to fabricate a conductive printed pattern utilizing, for example, ink jet printing; copper metal should be reduced to fine particles in the micrometer/submicrometer scale.

Conductive Copper inks (e.g., Copper “nanoinks”), can be used as a low-cost replacement for silver and gold nanoinks that are used in inkjet printing of conductive patterns. Copper inks containing nanoparticles can be used in the fabrication of a variety of printed electronics, such as flexible printed circuits (FPCs), and printed circuit boards (PCBs) and their combination (e.g., rigid-flex PCBs). In order to comply with the requirements of drop-on demand (DOD) digital printing by ink-jet technology, the nanoinks must possess the appropriate properties of viscosity, surface tension, density, particles size and stability. For the deposited nanoparticles to form an efficient conductive pattern (or trace), the active component of the printed material should form a dense packing array, which has the ability to more efficiently and effectively conduct electricity throughout the traces' volume.

The performance properties of metal nanoinks are closely related to the size, shape, size distribution, and colloidal suspension of the nanoparticles contained in the ink. Typically, a uniform shape and size of nanoparticles are important for optimizing the packing factor, obtaining high internal phase leading to higher electrical conductivity values of ink-jetted traces.

Unfortunately, Copper is easily oxidized and the oxide is non-conductive. this phenomenon is greatly enhanced in the transfer from bulk materials to the micrometer scale. Conventional Copper-based nanoparticle inks are unstable and require an inert/reducing atmosphere during preparation and sintering in order to prevent spontaneous oxidation to non-conductive CuO or Cu₂O. Copper polymer thick film (PTF) inks have been available for many years and can be used for special purposes, for example, where solderability is required. Another strategy is to combine the advantages of both silver and copper. Silver plated Copper particles are commercially available, and are used in some commercially available inks. Silver plating provides the advantages of silver for inter-particle contacts and as an Oxygen diffusion barrier, while using the cheaper conductive metal (Copper) for the bulk of the particle material. However, their cost is still higher in comparison to pure copper particles.

Accordingly, there is a need for oxidation resistant Copper nanoparticles that can be jetted under ambient, atmospheric conditions yet still capable of providing high conductivity.

### SUMMARY

Disclosed, in various embodiments, are oxidation-resistant conductive ink composition comprising discrete flocculates of metallic, geometrically discrete nanoparticles, configurations, methods for their synthesis and the conductive nanoinks formed therefrom. Specifically, provided herein are methods and compositions for forming nano@micro clusters (flocculates) of flocculated nanoparticles of oxidation-resistant copper nanoparticles having a discrete spatial configuration. Upon sintering, although an oxidized shell may form on the surface of the flocculates, a core of non-oxidized copper nanoparticles will still remain at concentration above the 3D bond percolation threshold to ensure conductivity of the trace.

In an embodiment provided herein is an oxidation resistant conductive ink composition comprising a plurality of flocculates, each flocculate comprising a plurality of metallic, geometrically discrete nanoparticles, the plurality of flocculates having a predetermined D_{3,2} particle size distribution, wherein each flocculate comprises a shell, comprised of a first portion of the plurality of metallic, geometrically discrete nanoparticle, encapsulating a core of a second portion of the plurality of metallic, geometrically discrete nanoparticles.

In another embodiment, provided herein is a method of forming a flocculates of a plurality of geometrically discrete copper nanoparticles comprising: Admixing a copper precursor into a stabilizer-solvent mixture, forming stabilized copper precursors/salt/ion dispersion; Contacting the stabilized copper dispersion with a reducer under ambient conditions adapted to form the discrete size flocculates; and washing the reduced stabilized copper dispersion, wherein the reducing agent is configured to react with the copper precursor and forms elemental Copper.

In yet another embodiment, provided herein is a method of printing a conductive trace on a substrate using inkjet printer, comprising: providing an inkjet printing system comprising: a first print head having: at least one aperture, a conductive ink reservoir, and a conductive pump configured to supply conductive ink through the aperture; a conveyor, operably coupled to the first print head, configured to convey a substrate to the first print head; providing any of the embodiments of the conductive ink compositions having flocculates of a plurality of geometrically discrete copper nanoparticles provided herein; using the first inkjet print head, ejecting the conductive ink composition onto the substrate forming a trace; and sintering the printed trace.

The term “flocculation” as used herein refers to the agglomeration of geometrically discrete Copper nanoparticles resulting from bridging between the nanoparticles by the components of the admixture used in the synthesis of the geometrically discrete Copper nanoparticles, or other polymers. Furthermore, as used herein, the term “flocculates” is used interchangeably with the term “floc”, meaning flocculation, combination, or aggregation of suspended geometrically discrete, oxidation-resistant Copper nanoparticles in such a way that they form small clumps, clusters, or tufts; and also refers in another embodiment to the flocculent mass formed as an aggregate or precipitate comprising the geometrically discrete Copper nanoparticles.

In an embodiment, the geometrically discrete Copper nanoparticles used in the ink compositions described, and used in the methods provided, are elemental Copper (Cu) discrete flocculates of a plurality of geometrically discrete copper nanoparticles before sintering using appropriate reducing agents to Copper salts that are, for example, Cu formate, CuCl, CuCl₂, CuBr, CuSO₄, Cu (I) Acetate, Cu (II) acetate, Cu acetylacetonate, Cu(NO₃)₂, Cu(CN)₂, Cu(OH)₂, CuCrO₄, CuCO₃, Cu(OSO₂CF₃)₂, Cu₂S, CuI, Cu(C₆H₅CO₂)₂, CuS, Copper(II) 2-ethylhexanoate, or a combination thereof, later forming an ink composition.

These and other features of the flocculates of a plurality of geometrically discrete copper nanoparticles, their methods of synthesis and their use as conductive inks will become apparent from the following detailed description when read in conjunction with the figures and examples, which are exemplary, not limiting.

### BRIEF DESCRIPTION OF THE FIGURES

For a better understanding of the flocculates of a plurality of geometrically discrete copper nanoparticles, their methods of synthesis and their use as conductive inks, with regard to the embodiments thereof, reference is made to the accompanying examples and figures, in which:

FIG. 1 shows (scanning electron microscopy) SEM image at ˜4000× magnification of the flocculates on a substrate before sintering;

FIG. 2, shows SEM image at ˜12,200× magnification of the flocculates shown in FIG. 1;

FIG. 3, shows SEM image at ˜57,6000× magnification of the flocculates shown in FIG. 1.;

FIG. 4A, shows SEM image at ˜6,600× magnification of the sintered flocculates, with (focused ion beam) FIB image of the sintered flocculates at ˜800,000× magnification shown in FIG. 4B and FIB image at ˜100,000× magnification shown in FIG. 4C;

FIG. 5, illustrates an embodiment of the structure of the flocculates of a plurality of geometrically discrete copper nanoparticles;

FIG. 6 illustrates an embodiment of a discrete sintered flocculate; and

FIG. 7, is a schematic of an embodiment of the process used to form the flocculates of the plurality of geometrically discrete copper nanoparticles.

### DETAILED DESCRIPTION

Provided herein are embodiments of flocculates of a plurality of geometrically discrete copper nanoparticles, their methods of synthesis, assembly, and their use as conductive inks.

Metals that possess high conductivity (typically, 10⁵ S·cm⁻¹) and operational stability can be applied via inkjet printing in the form of nanoparticles in conductive inks. Because of their size, metal nanoparticles contained in the printed pattern can then be converted to conductive continuous metal traces via post-printing thermal sintering at much lower temperatures than the melting points of the corresponding bulk metals.

Copper has been proved to be a good alternative material as it is highly conductive but significantly cheaper than gold (Au) and silver (Ag). Several methods were developed for the preparation of Copper nanoparticles, for example; thermal reduction, sonochemical reduction, chemical reduction, and microemulsion techniques.

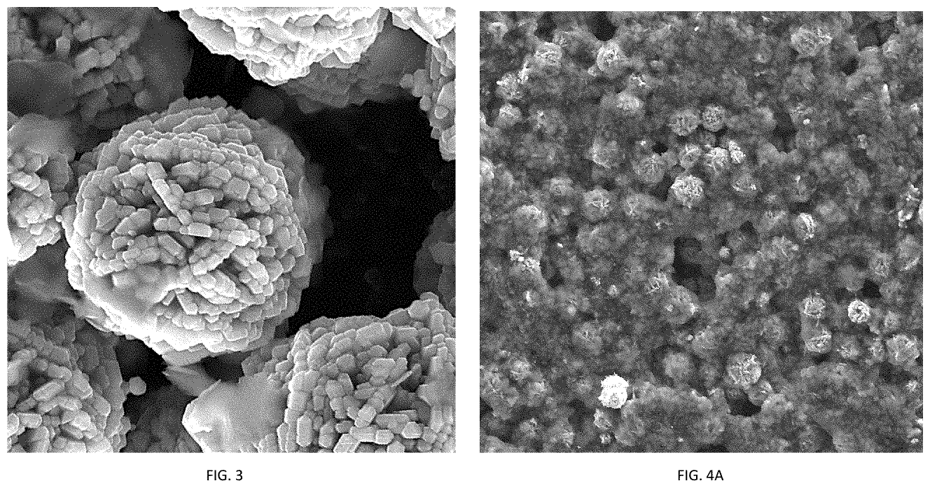

Surprisingly, the authors have found that when; through controlling reaction conditions, oxidation-resistant, geometrically discrete copper nanoparticles (e.g., elongated face-centered cubic particles, see e.g., FIG. 3) are caused to flocculate to form a nano@micro flocs, or clusters, it is possible to sinter traces made with composition comprising the flocculates (as well as, in certain embodiment, non-flocculated copper nanoparticles), at relatively low heat under ambient (non-inert) atmosphere without substantially detrimental oxidation, resulting in the sintered trace being conductive.

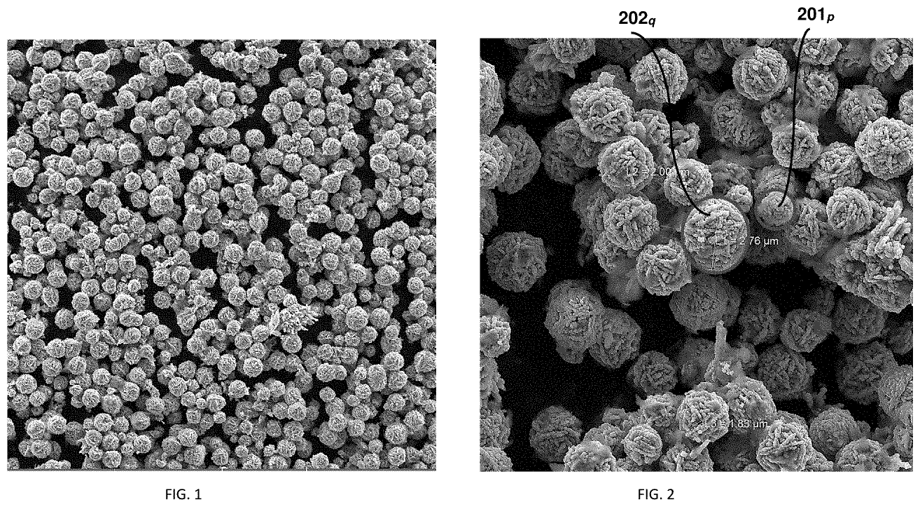

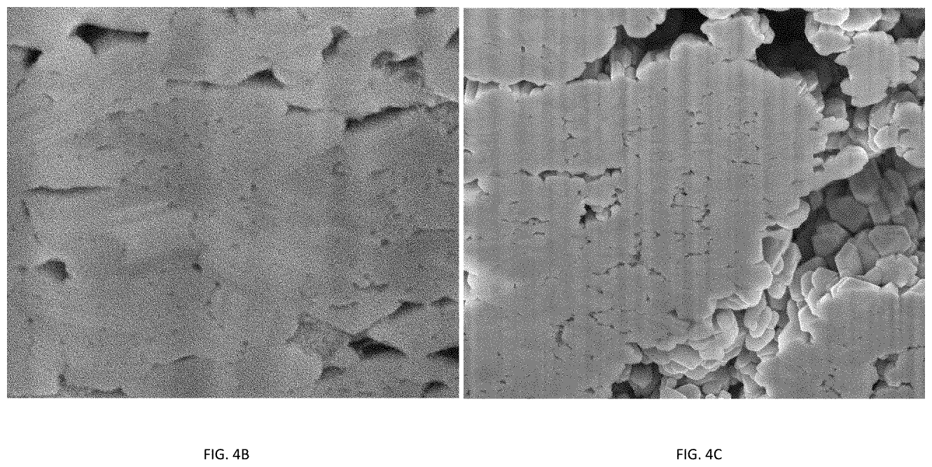

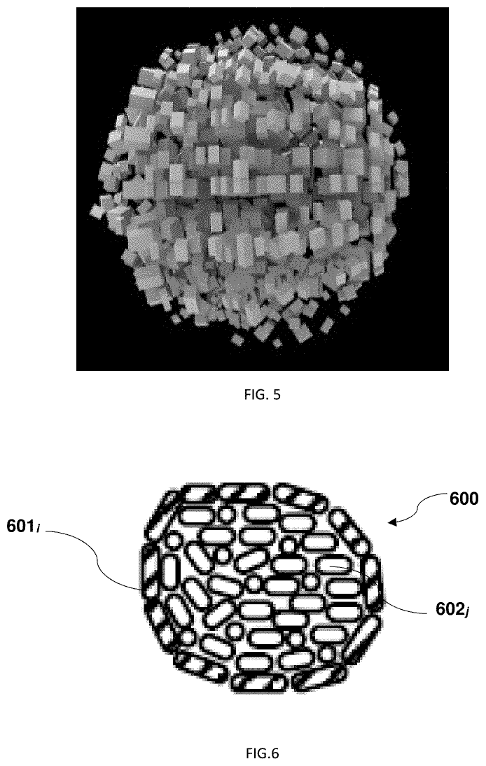

Also, the synthesis can be of monodispersed copper nanoparticles with high packing capabilities, having discrete geometric morphologies such as hexagonal, cubes (see e.g., FIGS. 2, 3, 5), rods and platelets. The discrete geometric morphologies can be configured to align and form a closed packed array (see e.g., FIGS. 2, 3, 5), while forming the flocculates (see e.g., FIGS. 1-3) and after sintering, forming a continuous trace of molten copper (see e.g., FIGS. 4B-5).

Accordingly and in an embodiment, provided herein is an oxidation resistant conductive ink composition comprising a plurality of flocculates, each flocculate comprising a plurality of metallic, geometrically discrete nanoparticles, the plurality of flocculates having a predetermined D_{3,2} particle size distribution, wherein (see e.g., FIG. 6) the each flocculate comprises shell 601ᵢ, comprised of a first portion of the plurality of metallic, geometrically discrete nanoparticles, encapsulating core 602ⱼ, of a second portion of the plurality of metallic, geometrically discrete nanoparticles.

The metallic, geometrically discrete nanoparticles used in the inks synthesized by the methods described herein, can be synthesized in a hydrophilic environment. The term “hydrophilic environment” refers in an embodiment to an environment energetically compatible with water, such as for example, a liquid environment where the bulk liquid is polar and wherein water solubility in the bulk is sufficiently high at room temperature and atmospheric pressure that the fractional concentration of water is more than about 55% (w/w).

Further, wherein the metallic, geometrically discrete nanoparticles used in the inks synthesized by the methods described herein, can be hexagonal, cubic (see e.g., FIGS. 2, 3, 5), rods, platelets, spherical or a combination comprising the foregoing, configured to form high internal phase ratio flocculates (HIPRF) (nanoparticles account for more than about 65% of the volume of the flocculate). The HIPRF will form a coherent trace once the ink comprising the HIPRF is printed using post-printing processes, for example, sintering, mild heating (e.g., between about 50° C. and about 250° C.).

In an embodiment, the predetermined D_{3,2} (i.e., volume average diameter) particle size distribution of the flocculates of the plurality of metallic, geometrically discrete nanoparticles (Cu nano@micro), used in the compositions synthesized by the methods described herein, can be configured to be monodispersed or exhibits a distribution with a predetermined ratio between modes. The predetermined mode ratio can be selected such that when the Cu nano@micro floc conformation can be spheres (see e.g., FIG. 2) with the smaller mode Cu nanoparticles, or smaller flocs 201ₚ, configured to be inscribed within the volume defined among every three of the larger mode spheres of Cu nano@micro flocs 202_{q}, packed in, for example, close hexagonal array (see e.g., FIG. 4C after sintering). In other words, the metallic, geometrically discrete nanoparticles can be configured to be a filler in the interstitial voids between adjacent flocs.

Alternatively or in addition, the metallic inks synthesized by the methods described herein can comprise a solution of reducible Copper salts. The copper salts can be, for example, Cu formate, CuCl, CuCl₂, CuBr, CuSO₄, Cu (I) Acetate, Cu (II) acetate, Cu acetylacetonate, Cu(NO₃)₂, Cu(CN)₂, Cu(OH)₂, CuCrO₄, CuCO₃, Cu(OSO₂CF₃)₂, Cu₂S, CuI, Cu(C₆H₅CO₂)₂, CuS, Copper(II) 2-ethylhexanoate, or a composition comprising one or more of the foregoing.

As indicated, and in another embodiment; the reducible copper precursors (salts) can be, for example, Cu(NO₃)₂ and/or Cu(Cl)₂, and/or Cu(SO₄), Cu₃(PO₄)₂, Cu(sodium bis(2-ethylhexyl) sulfosuccinate)₂, Cu(acetylacetonate)₂, or a composition of Copper ion source comprising one or more of the foregoing. In addition, the conductive ink can be in the form of a solution, an emulsion, a dispersion, or a gel and comprise all other medium components described herein except for the metal nanoparticles in one embodiment. In addition, the reducer of the floc synthesis composition can comprise a reducing agent, for example; Formic acid, Sodium borohydride, Hydrazine, Sodium formaldehyde sulfoxylate dehydrate, Ascorbic Acid, Oleylamine, Dextrose, Glucose, Ribose, Fructose, 1,2 Hexadecandiol, 3-mercaptopropoic acid, NaH2PO2*H2O, Benzyl Alcohol, Oxalic Acid, Dithiothreitol, CO, H2) or a reducing agent composition comprising one or more of the foregoing.

Alternatively, or in addition, the flocs of metallic, geometrically discrete nanoparticles used in the inks synthesized by the methods described herein, can form a core within a removable protective shell, wherein the shell is configured to be removed upon sintering. The removable shell can, for example, comprises carbon, a photoresist or a removable shell composition comprising the foregoing. The photoresist can be coated on the core providing additional barrier to Oxygen/moisture. Following deposition on the substrate using the inkjet print head described herein, the photoresist can be removed from the flocs (see e.g., FIG. 4A) using, for example, heat, UV light, intense pulsed light (IPL), or selective laser sintering (SLS), simultaneously removing the photoresist and sintering the Cu nano@micro flocs.

In general, there are two steps required for printing conductive patterns from conductive nanoinks: printing followed by first evaporation of the solvents and second sintering of the nano-particles which transforms the ink into a conductive, solid metal trace. The orifice plate can be configured as necessary for the purpose of high-resolution printed electronics. Accordingly, Cu nano@micro flocs has a volume average diameter (D_{3,2}) of between about 0.4 μm (400 nm), and about 4.0 μm and wherein the shell has a thickness of between about 4.0 nm and about 400 nm. Likewise, each oxidation resistant, geometrically discrete Cu nanoparticle used in the compositions and methods described herein, can have an average diameter (D_{3,2}) of between about 4.0 nm and about 400 nm

In an embodiment, the volume of each droplet of the conductive (or metallic) ink jetted from the orifice plate, can range from 0.5 to 300 picoLiter (pL), for example 1-4 pL and depended on the strength of the driving pulse and the properties of the ink. The waveform to expel a single droplet can be a 10V to about 70 V pulse, or about 16V to about 20V, and can be expelled at frequencies between about 5 kHz and about 50 kHz.

To facilitate printing through a piezoelectric chamber, the ink used in the inks synthesized by the methods described herein, can have apparent viscosity (hᵥ) of between about 8 cP and about 15 cP, at the printing temperature and have liquid/air surface tension (σₐₗ) of between about 25 dynes/cm and about 35 dynes/cm. This interfacial tension can be beneficial in ensuring the formation of a precise trace, without the formation of coffee rings/bulges and create good adhesion to the substrate surface. In an embodiment, the apparent viscosity of the conductive ink composition, can be between about 0.1 and about 30 cP (mPa·s), for example the final ink formulation can have a viscosity of 8-12 cP at the working temperature, which can be controlled. For example, the flocs comprising the plurality of Cu nano-particles or the resin inkjet ink can each be between about 5 cP and about 25 cP, or between about 7 cP and about 20 cP, specifically, between about 8 cP and about 15 cP.

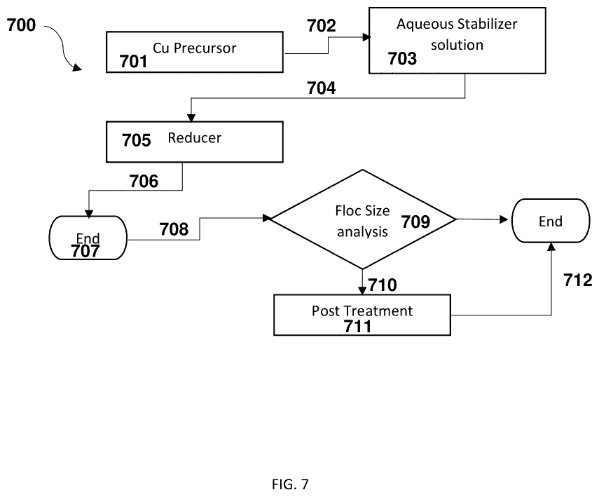

In an embodiment, the compositions described herein, are used in the methods provided herein. Accordingly (see e.g., FIG. 7) and in an embodiment, provided herein is a method of forming flocculates (flocs) of a plurality of geometrically discrete copper nanoparticles (e.g., Cu nano@micro flocs) comprising: admixing 702 copper precursor 701 into stabilizer-solvent mixture 703, forming stabilized copper dispersion, followed by contacting 704 the stabilized copper dispersion with a reducing agent 705 under ambient conditions. Each step, in other words, admixing 702, and contacting 704 is controlled in terms of time and temperature to achieve the proper Cu nanoparticles and the resulting flocs. Other factors affecting the floc size can be, for example, stirring type and speed, reactants type and ratio, reaction volume and the like. Following contacting the stable copper dispersion with the reducer, or reducing solution in another embodiment, the reactants are maintained 706, stirred under controlled temperature for a period of between about 1 hour and 24 hours, which marks the end 707 of the reaction. Following the predetermined allotted time configured to form the flocs with the appropriate size, post treatment 711 is carried out, to remove excess reactants. In an embodiment, post treatment can comprise centrifugation and washing using for example solvent like water 707, or otherwise, for example after analyzing floc size 709, performing post treatment 711 on the floc population.

In an embodiment, post treatment 711 may be beneficial to obtain the proper floc size to ensure sintering at low temperatures, for example average floc diameter D_{3,2} size can be between about 0.4μ and about 1.6 μm, configured to yield sintering temperature of between about 50° C. and about 120° C. Accordingly, low temperature sintering of metal NP ink can be advantageous in many applications, for example; on flexible film such as amorphous poly(ethylenetheraphthalate) (aPET), which can only withstand processing temperatures of between about 100° C.-and about 150° C., used in such applications as RFIDs, antenna, membrane switches and sensors. Furthermore, low temperature sintering can be configured to enable printing on flexible film in a roll-to-roll printer may be advantageous for mass production applications, which require high speed, and thus, the less energy required for sintering, the better and faster speeds are enabled. In addition, obtaining the floc size as described herein, configured to provide for low temperature sintering as described herein can be used to simplify the printing process for multi-material applications, for example for printing on paper.

The stabilizer can comprise a binding functionality selected from the group consisting of thiol, selenol, amine, phosphine, phosphine oxide, carboxylic or ether or For example, the stabilizer used in the synthesis by the methods described herein, can be polydiallyldimethyl (PDDM), polyimines (PI), polycarboxylatethers (PCE), polyacrylic acids (PAA), polyvinylpirrolidone (PVP), proteins, polypyrrol, polysaccharides, poly(vinyl alcohol) (PVA), Ethylen Glycol, Triphenylphosphine oxide (TPPO), Ethylendiamine (EDA), Amino Acids, Aminomethyl propanol, cetyltrimethyl ammonium bromide (CTAB), cetyltrimethylammonium chloride (CTAC), poly(oxyethylene) 10 eleoyl ether (BRIJ 96), Polyoxyethylenesorbitan monooleate (Tween 80), Oleic Acid, Hexadecyl amine Hexanoic acid, Ethylene glycol, Trioctylphosphine, Trioctylphosphine oxide, Oxadecylamine, Sodium Citrate or a combination comprising one or more of the foregoing.

As used herein, when referring to relatively low sintering temperature, depending on the size and size distribution of the Cu nano@micro flocs, sintering temperature can be between about 23° C. and about 250° C., or between about 50° C. and about 200° C., for example, between about 60° C. and about 200° C., or between about 60° C. and about 180° C.,

Likewise, the solvent, co-solvent or a combination comprising the foregoing used in the inks synthesized by the methods described herein, can be for example, Octyl ether, Water, Ethylene Glycol, Polyethylene glycol, Ethanediol, Cyclohexane, Butanol, 1,3-Propanediol, or a combination comprising the foregoing.

In an embodiment, the flocculation can be controlled by predetermining the reactants ratios. For example, the ratio between the copper precursor and the stabilizing agents (in other words, stabilizer) can be between about 10:1 and 1:10 (w/w), while the ratio between the copper precursor and the reducing agent (in other words, the reducer) can be between about 1:0.5 and about 1:10 moles. Likewise, synthesis time, temperature and reaction volume can be controlled to induce (in combination with the proper reactants' type, concentration and ratios) flocs of the desired size. For example, simultaneous synthesis of geometrically discrete, oxidation-resistant Cu nanoparticles and their flocculation can be carried out at temperatures of between about 22° C. and about 200° C., for a period, (that is temperature-dependent) of between about 1 hour and about 24 hours.

Depending on the obtained floc, it may be necessary to perform various post treatment steps, For example, centrifugation and redispersion of the flocs and remaining geometrically discrete, oxidation-resistant Cu nanoparticles, or other steps such as passing the sample through a Buchner funnel, preparatory (size-exclusion e.g.) HPLC, and the like. The post processing methods and techniques used are configured to obtain the desired floc size, size distribution that can be sintered at the relatively low sintering temperatures, without oxidizing a substantial portion of the core, thus yielding the desired conductivity upon sintering.

Once having the desired copper flocculates, an ink-jet ink formulation is composed which allows for proper drop-on-demand printing through tuning of viscosity, surface tension density and stability parameters.

In an embodiment, the nanoinks produced may require the presence of a surfactant and a cosurfactants. The surfactants and/or cosurfactants may be anionic surfactants, non-ionic surfactant and polymers, for example amphiphilic copolymers, such as block copolymers.

Example of non-ionic surfactants and/or cosurfactants may be: polyoxyethylene fatty alcohol ethers, polyoxyethylene sorbitan fatty acid esters, polyoxyethylene fatty acid esters, polyoxyethylene-derivatized lipids such as Mpeg-PSPC (palmitoyl-stearoyl-phophatidylcholine), Mpeg-PSPE (palmitoyl-stearoyl-phophatidylethanolamine), sorbitan esters, glycerol monostearate, polyethylene glycols, polypropylene glycols, cetyl alcohol, cetostearyl alcohol, stearyl alcohol, aryl alkyl polyether alcohols, polyoxyethylene-polyoxypropylene copolymers, polaxamines, methylcellulose, hydroxycellulose, hydroxy propylcellulose, hydroxy propylmethylcellulose, noncrystalline cellulose, polysaccharides, starch, starch derivatives, hydroxyethylstarch, polyvinyl alcohol, and polyvinylpyrrolidone.

Examples of anionic surfactants and/or cosurfactants may be: sulfonic acids and their salt derivatives; alkali metal sulfosuccinates; sulfonated glyceryl esters of fatty acids such as sulfonated monoglycerides of coconut oil acids; salts of sulfonated monovalent alcohol esters such as sodium oleyl isothionate; amides of amino sulfonic acids such as the sodium salt of oleyl methyl tauride; sulfonated products of fatty acid nitriles such as palmitonitrile sulfonate; sulfonated aromatic hydrocarbons such as sodium alpha-naphthalene monosulfonate; condensation products of naphthalene sulfonic acids with formaldehyde; sodium octahydro anthracene sulfonate; alkali metal alkyl sulfates such as sodium lauryl (dodecyl) sulfate (SDS); ether sulfates having alkyl groups of eight or more carbon atoms; and alkylaryl sulfonates having one or more alkyl groups of eight or more carbon atoms.

Other surfactants and/or cosurfactants and/or stabilizers useful in the methods described herein can be cetyltrimethyl ammonium bromide, cetyltrimethylammonium chloride, poly(oxyethylene) 10 eleoyl ether (BRIJ 96), Polyoxyethylenesorbitan monooleate (Tween 80), Oleic Acid, Hexadecyl amine Hexanoic acid, Ethylene glycol, Trioctylphosphine, Trioctylphosphine oxide, Oxadecylamine, Sodium Citrate or a combination comprising one or more of the foregoing.

The inkjet printers utilizing the inks and compositions described herein can further comprise other functional heads that may be located before, between or after the conductive (metal containing) print head. These functional heads may include a source of electromagnetic radiation configured to emit electromagnetic radiation at a predetermined wavelength (X), for example, between 190 nm and about 400 nm, e.g. 365 nm which in an embodiment, can be used to accelerate and/or modulate and/or facilitate a photopolymerizable dispersant that can be used on conjunction with metal nanoparticles used in the conductive ink. Other functional heads can be heating and/or irradiation elements, additional printing heads with various inks (e.g., pre-soldering connective ink, label printing of various components for example capacitors, transistors and the like) and a combination of the foregoing.

Moreover, other similar functional steps (and therefore means for affecting these steps) may be taken before or after the metal/conductive print head (e.g., for curing the conductive layer). These steps may include (but not limited to): a heating step (affected by a heating element, or hot air); photobleaching (using e.g., a UV light source and a photo mask); drying (e.g., using vacuum region, or heating element); (reactive) plasma deposition (e.g., using pressurized plasma gun and a plasma beam controller); cross linking (e.g., by selectively initiated through the addition of a photoacid such as {4-[(2-hydroxytetradecyl)-oxyl]-phenyl}-phenyliodonium hexafluoro antimonate to a resin polymer solutions prior to coating or used as dispersant with the metal precursor, nanoparticles or flocs); or annealing.

In certain embodiment, a laser (for example, selective laser sintering/melting, direct laser sintering/melting), or electron-beam melting can be used on the printed traces.

Formulating the conductive ink compositions described herein, may take into account the requirements, if any, imposed by the deposition tool (e.g., in terms of viscosity and surface tension of the composition, for example when using a Copper and or Copper metal core shell nanoparticles) and the surface characteristics (e.g., hydrophilic or hydrophobic, and the interfacial energy of the substrate).

Using for example, inkjet printing with a piezo head, the viscosity of the conductive ink (measured at 20° C.) can be, for example, not lower than about 5 cP, e.g., not lower than about 8 cP, or not lower than about 10 cP, and not higher than about 30 cP, e.g., not higher than about 20 cP, or not higher than about 15 cP. The conductive ink, can be configured (e.g., formulated) to have a dynamic surface tension (referring to a surface tension when an ink-jet ink droplet is formed at the print-head aperture) of between about 15 mN/m and about 35 mN/m, for example between about 29 mN/m and about 31 mN/m measured by maximum bubble pressure tensiometry at a surface age of 50 ms and at 25° C. The dynamic surface tension can be formulated to provide a contact angle with the substrate of between about 100° and about 165°.

Using the Copper ink composition comprising the Cu nano@micro flocs in the methods described herein, can be composed essentially of conductive Copper, a binder, and a solvent, wherein the diameter, shape and composition ratio of the flocs in the ink are optimized, thus enabling the formation of a layer, or printed circuit having a high aspect ratio (in other words, rods, see e.g., FIG. 3) and exhibiting superior electrical properties. These rods can be in a size range suitable for electronic applications. In an embodiment, conductive circuit pattern formed using ink suspensions of Cu nano@micro flocs that can be significantly enhanced in sintering quality, and wherein the Cu nanoparticles in the nano@micro flocs have thin or small features with high aspect ratios (e.g., platelets, or rods). In other words, Cu nanoparticles aspect ratio R is much higher than 1 (R>>1). Having the high aspect ratio can produce dense packing, which will, upon sintering promote bond percolation higher than the 3D percolation threshold (see e.g., FIG. 5).

Similarly, in another embodiment, the flocs may be configured to form packing arrangements of Cu nanoparticles that will cause flocs of predetermined spatial configuration, for example, cubic arrangements, rod-like arrangements or oblong, egg-shaped arrangements.

In an embodiment, the inkjet ink compositions and methods for forming Copper traces can be patterned by expelling droplets of the conductive inkjet ink provided herein from an orifice one-at-a-time, as the print-head (or the substrate) is maneuvered, for example in two (X-Y) (it should be understood that the print head can also move in the Z axis) dimensions at a predetermined distance above the removable substrate or any subsequent layer. The height of the print head can be changed with the number of layers, maintaining for example a fixed distance. Each droplet can be configured to take a predetermined trajectory to the substrate on command by, for example a pressure impulse, via a deformable piezo-crystal in an embodiment, from within a well operably coupled to the orifice. The printing of the first inkjet conductive ink can be additive and can accommodate a greater number of layers. The ink-jet print heads provided used in the methods described herein can provide a minimum layer film thickness equal to or less than about 5 μm-10,000 μm, with a single pass trace thickness that depends on, for example, the nanoparticles' size and the concentration of the particles within the ink composition.

The substrate film or sheet on which the traces are printed, can be positioned on a conveyor moving at a velocity of between about 5 mm/sec and about 1000 mm/sec. The velocity of the substrate can depend, for example, on the number of print heads used in the process, the number and thickness of layers of the components printed, the curing time of the ink, the evaporation rate of the ink solvents, the removal rate of the medium-boiling solvents and/or co-solvents, the distance between the print head containing the conductive ink of the Cu flocculates and the additional functional print heads, and the like or a combination of factors comprising one or more of the foregoing.

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

All ranges disclosed herein are inclusive of the endpoints, and the endpoints are independently combinable with each other. “Combination” is inclusive of blends, mixtures, alloys, reaction products, and the like. The terms “a”, “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the particle(s) includes one or more particles). Reference throughout the specification to “one embodiment”, “another embodiment”, “an embodiment”, and so forth, when present, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments.

All ranges disclosed herein are inclusive of the endpoints, and the endpoints are independently combinable with each other. Furthermore, the terms “first,” “second,” and the like, herein do not denote any order, quantity, or importance, but rather are used to denote one element from another.

Likewise, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

Accordingly and in an embodiment, provided herein is a oxidation resistant conductive ink composition comprising a plurality of flocculates, each flocculate comprising a plurality of metallic, geometrically discrete nanoparticles, the plurality of flocculates having a predetermined D_{3,2} particle size distribution, wherein each flocculate comprises a shell, comprised of a first portion of the plurality of metallic, geometrically discrete nanoparticle, encapsulating a core of a second portion of the plurality of metallic, geometrically discrete nanoparticles, wherein (i) the metallic, geometrically discrete nanoparticles are hexagonal, cubic, rods, platelets, spherical or a combination comprising the foregoing, wherein (ii) the plurality of metallic, geometrically discrete nanoparticles are copper hexagonal lattice (Cu) nanoparticles, wherein (iii) the predetermined D_{3,2} particle size distribution of the flocculates is configured to enable sintering of the oxidation resistant conductive ink composition at a temperature of between about 50° C. and about 250° C., or (iv) between about 50° C. and about 120° C., (v) the predetermined D_{3,2} particle size distribution of the flocculates is between about 0.4 μm, and about 4.0 μm, wherein (vi) following sintering, the shell comprises between about 0% and about 50% of the total number of the metallic, geometrically discrete nanoparticle, (vii) the shell is oxidized, wherein (viii) the flocculates are aggregated in the presence of a composition comprising a copper precursor, a stabilizing agent, a solvent, and a reducer, (ix) the copper precursor is a composition comprising Cu formate, CuCl, CuCl₂, CuBr, CuSO₄, Cu (I) Acetate, Cu (II) acetate, Cu acetylacetonate, Cu(NO₃)₂, Cu(CN)₂, Cu(OH)₂, CuCrO₄, CuCO₃, Cu(OSO₂CF₃)₂, Cu₂S, CuI, Cu(C₆H₅CO₂)₂, CuS, Copper(II) 2-ethylhexanoate, or a composition comprising one or more of the foregoing, (x) the stabilizing agent polydiallyldimethyl (PDDM), polyimines (PI), polycarboxylatethers (PCE), polyacrylic acids (PAA), polyvinylpirrolidone (PVP), proteins, polypyrrol, polysaccharides, poly(vinyl alcohol) (PVA), Ethylen Glycol, Triphenylphosphine oxide (TPPO), Ethylendiamine (EDA), Amino Acids, Aminomethyl propanol, cetyltrimethyl ammonium bromide (CTAB), cetyltrimethylammonium chloride (CTAC), poly(oxyethylene) 10 eleoyl ether (BRIJ 96), Polyoxyethylenesorbitan monooleate (Tween 80), Oleic Acid, Hexadecyl amine Hexanoic acid, Ethylene glycol, Trioctylphosphine, Trioctylphosphine oxide, Oxadecylamine, Sodium Citrate, or a combination comprising one or more of the foregoing, (xi) the reducer is Formic acid, Sodium borohydride, Hydrazine, Sodium formaldehyde sulfoxylate dehydrate, Ascorbic Acid, Oleylamine, Dextrose, Glucose, Ribose, Fructose, 1,2 Hexadecandiol, 3-mercaptopropoic acid, NaH2PO2*H2O, Benzyl Alcohol, Oxalic Acid, Dithiothreitol, CO, H2) or a reducing agent composition comprising one or more of the foregoing, and wherein (xii) each of the metallic, geometrically discrete nanoparticle has an average diameter (D_{3,2}) of between about 8 nm and about 120 nm and wherein the shell has a thickness of between about 4 nm and about 400 nm.

In another embodiment, provided herein is a method of forming a flocculates of a plurality of geometrically discrete copper nanoparticles comprising: admixing a copper precursor into a stabilizer-solvent mixture, forming stabilized copper precursors/salt/ion dispersion; contacting the stabilized copper dispersion with a reducer under ambient conditions adapted to form the discrete size flocculates; and washing the reduced stabilized copper dispersion, wherein the reducing agent is configured to react with the copper precursor and forms elemental Copper, wherein (xiii) each of the plurality of geometrically discrete copper nanoparticles is hexagonal, cubic, rod, platelet, spherical or a combination comprising the foregoing, wherein (xiv) the step of washing comprises removing excess reactants while inhibiting flocculate growth (xv) by controlled stirring, temperature control, reaction time and reaction volume control, and their combination, wherein (xvi) the step of washing is repeated between 1 and 3 times, wherein (xvii) the copper precursor is a composition comprising Cu formate, CuCl, CuCl₂, CuBr, CuSO₄, Cu (I) Acetate, Cu (II) acetate, Cu acetylacetonate, Cu(NO₃)₂, Cu(CN)₂, Cu(OH)₂, CuCrO₄, CuCO₃, Cu(OSO₂CF₃)₂, Cu₂S, CuI, Cu(C₆H₅CO₂)₂, CuS, Copper(II) 2-ethylhexanoate, or a composition comprising one or more of the foregoing, (xviii) the stabilizing agent is polydiallyldimethyl (PDDM), polyimines (PI), polycarboxylatethers (PCE), polyacrylic acids (PAA), polyvinylpirrolidone (PVP), proteins, polypyrrol, polysaccharides, poly(vinyl alcohol) (PVA), Ethylen Glycol, Triphenylphosphine oxide (TPPO), Ethylendiamine (EDA), Amino Acids, Aminomethyl propanol, cetyltrimethyl ammonium bromide (CTAB), cetyltrimethylammonium chloride (CTAC), poly(oxyethylene) 10 eleoyl ether (BRIJ 96), Polyoxyethylenesorbitan monooleate (Tween 80), Oleic Acid, Hexadecyl amine Hexanoic acid, Ethylene glycol, Trioctylphosphine, Trioctylphosphine oxide, Oxadecylamine, Sodium Citrate or a combination comprising one or more of the foregoing, (xix) the reducer is Formic acid, Sodium borohydride, Hydrazine, Sodium formaldehyde sulfoxylate dehydrate, Ascorbic Acid, Oleylamine, Dextrose, Glucose, Ribose, Fructose, 1,2 Hexadecandiol, 3-mercaptopropoic acid, NaH2PO2*H2O, Benzyl Alcohol, Oxalic Acid, Dithiothreitol, CO, H2, or a reducing agent composition comprising one or more of the foregoing, wherein the methods described are (xx) configured to form a flocculate comprised of a shell of a first portion of the plurality of geometrically discrete copper nanoparticle, encapsulating a core of a second portion of the plurality of geometrically discrete copper nanoparticles.

While particular embodiments have been described, alternatives, modifications, variations, improvements, and substantial equivalents that are or may be presently unforeseen may arise to applicants or others skilled in the art. Accordingly, the appended claims as filed and as they may be amended, are intended to embrace all such alternatives, modifications variations, improvements, and substantial equivalents.

1. An oxidation resistant conductive ink composition comprising a plurality of flocculates, each flocculate comprising a plurality of metallic, geometrically discrete nanoparticles, the plurality of flocculates having a predetermined D_{3,2} particle size distribution,
wherein each flocculate comprises a shell, comprised of a first portion of the plurality of metallic, geometrically discrete nanoparticle, encapsulating a core of a second portion of the plurality of the same metallic, geometrically discrete nanoparticles.

2. The composition of claim 1, wherein the metallic, geometrically discrete nanoparticles are hexagonal, cubic, rods, platelets, spherical or a combination comprising the foregoing.

3. The composition of claim 2, wherein the plurality of metallic, geometrically discrete nanoparticles are copper hexagonal lattice (Cu) nanoparticles.

4. The composition of claim 3, wherein the predetermined D_{3,2} particle size distribution of the flocculates is configured to enable sintering of the oxidation resistant conductive ink composition at a temperature of between about 50° C. and about 250° C.

5. The composition of claim 5, wherein the predetermined D_{3,2} particle size distribution of the flocculates is between about 0.4 μm, and about 4.0 μm.

6. The composition of claim 4, wherein following sintering, the shell comprises between about 0% and about 50% of the total number of the metallic, geometrically discrete nanoparticle.

7. The composition of claim 6, wherein the shell is oxidized.

8. The composition of claim 4, wherein the flocculates are aggregated in the presence of a composition comprising a copper precursor, a stabilizing agent, a solvent, and a reducer.

9. The composition of claim 8, wherein the copper precursor is a composition comprising Cu formate, CuCl, CuCl₂, CuBr, CuSO₄, Cu (I) Acetate, Cu (II) acetate, Cu acetylacetonate, Cu(NO₃)₂, Cu(CN)₂, Cu(OH)₂, CuCrO₄, CuCO₃, Cu(OSO₂CF₃)₂, Cu₂S, CuI, Cu(C₆H₅CO₂)₂, CuS, Copper(II) 2-ethylhexanoate, or a composition comprising one or more of the foregoing.

10. The composition of claim 8, wherein the stabilizing agent polydiallyldimethyl (PDDM), polyimines (PI), polycarboxylatethers (PCE), polyacrylic acids (PAA), polyvinylpirrolidone (PVP), proteins, polypyrrol, polysaccharides, poly(vinyl alcohol) (PVA), Ethylen Glycol, Triphenylphosphine oxide (TPPO), Ethylendiamine (EDA), Amino Acids, Aminomethyl propanol, cetyltrimethyl ammonium bromide (CTAB), cetyltrimethylammonium chloride (CTAC), poly(oxyethylene) 10 eleoyl ether (BRIJ 96), Polyoxyethylenesorbitan monooleate (Tween 80), Oleic Acid, Hexadecyl amine Hexanoic acid, Ethylene glycol, Trioctylphosphine, Trioctylphosphine oxide, Oxadecylamine, Sodium Citrate, or a combination comprising one or more of the foregoing.

11. The composition of claim 10, wherein the reducer is Formic acid, Sodium borohydride, Hydrazine, Sodium formaldehyde sulfoxylate dehydrate, Ascorbic Acid, Oleylamine, Dextrose, Glucose, Ribose, Fructose, 1,2 Hexadecandiol, 3-mercaptopropoic acid, NaH2PO2*H2O, Benzyl Alcohol, Oxalic Acid, Dithiothreitol, CO, H2) or a reducing agent composition comprising one or more of the foregoing.

12. The composition of claim 4, wherein each of the metallic, geometrically discrete nanoparticle has an average diameter (D_{3,2}) of between about 8 nm and about 120 nm and wherein the shell has a thickness of between about 4 nm and about 400 nm.

13. A method of forming flocculates of a plurality of geometrically discrete copper nanoparticles comprising:
a. admixing a copper precursor into a stabilizer-solvent mixture, forming stabilized copper precursors/salt/ion dispersion;
b. contacting the stabilized copper dispersion with a reducer under ambient conditions adapted to form the discrete size flocculates; and
c. washing the reduced stabilized copper dispersion, wherein the reducing agent is configured to react with the copper precursor and forms elemental Copper.

14. The method of claim 13, wherein each of the plurality of geometrically discrete copper nanoparticles is hexagonal, cubic, rod, platelet, spherical or a combination comprising the foregoing.

15. The method of claim 14, wherein the step of washing comprises removing excess reactants while inhibiting flocculate growth.

16. The method of claim 15, wherein the step of washing is repeated between 1 and 3 times.

17. The method of claim 13, wherein the copper precursor is a composition comprising Cu formate, CuCl, CuCl₂, CuBr, CuSO₄, Cu (I) Acetate, Cu (II) acetate, Cu acetylacetonate, Cu(NO₃)₂, Cu(CN)₂, Cu(OH)₂, CuCrO₄, CuCO₃, Cu(OSO₂CF₃)₂, Cu₂S, CuI, Cu(C₆H₅CO₂)₂, CuS, Copper(II) 2-ethylhexanoate, or a composition comprising one or more of the foregoing.

18. The method of claim 13, wherein the stabilizing agent is polydiallyldimethyl (PDDM), polyimines (PI), polycarboxylatethers (PCE), polyacrylic acids (PAA), polyvinylpirrolidone (PVP), proteins, polypyrrol, polysaccharides, poly(vinyl alcohol) (PVA), Ethylen Glycol, Triphenylphosphine oxide (TPPO), Ethylendiamine (EDA), Amino Acids, Aminomethyl propanol, cetyltrimethyl ammonium bromide (CTAB), cetyltrimethylammonium chloride (CTAC), poly(oxyethylene) 10 eleoyl ether (BRIJ 96), Polyoxyethylenesorbitan monooleate (Tween 80), Oleic Acid, Hexadecyl amine Hexanoic acid, Ethylene glycol, Trioctylphosphine, Trioctylphosphine oxide, Oxadecylamine, Sodium Citrate or a combination comprising one or more of the foregoing.

19. The method of claim 13, wherein the reducer is Formic acid, Sodium borohydride, Hydrazine, Sodium formaldehyde sulfoxylate dehydrate, Ascorbic Acid, Oleylamine, Dextrose, Glucose, Ribose, Fructose, 1,2 Hexadecandiol, 3-mercaptopropoic acid, NaH2PO2*H2O, Benzyl Alcohol, Oxalic Acid, Dithiothreitol, CO, H2, or a reducing agent composition comprising one or more of the foregoing.

20. The method of claim 13, configured to form a flocculate comprised of a shell of a first portion of the plurality of geometrically discrete copper nanoparticle, encapsulating a core of a second portion of the plurality of geometrically discrete copper nanoparticles.
